(19) United States
(12) Patent Application Publication
(10) Pub. No.: US 2024/0379722 A1
(43) Pub. Date: Nov. 14, 2024

(54) SEMICONDUCTOR DEVICE AND IMAGE SENSOR INCLUDING THE SAME

(71) Applicant: SAMSUNG ELECTRONICS CO., LTD., Suwon-si (KR)

(72) Inventor: Changyong UM, Suwon-si (KR)

(21) Appl. No.: 18/520,934

(22) Filed: Nov. 28, 2023

(30) Foreign Application Priority Data
May 9, 2023 (KR) 10-2023-0059949

(51) Int. Cl. H01L 27/146

(52) U.S. Cl. CPC H01L 27/14643; H01L 27/14603; H01L 27/1463

(57) ABSTRACT

A semiconductor device, including a gate electrode, a first region under the gate electrode and extending from a first direction to a second direction crossing the first direction, the first region having a bent shape, a first source-drain region extending from one end of the first region, a second source-drain region extending from an opposite end of the first region, and a third source-drain region at a point where a first virtual straight line extending from the first source-drain region in the first direction and a second virtual straight line extending from the second source-drain region in a direction opposite to the second direction cross each other in the first region, wherein the third source-drain region forms a first channel region together with the first source-drain region and forms a second channel region together with the second source-drain region.

### CROSS-REFERENCE TO RELATED APPLICATIONS

This application claims priority under 35 U.S.C. § 119 to Korean Patent Application No. 10-2023-0059949 filed on May 9, 2023, in the Korean Intellectual Property Office, the disclosures of which are incorporated by reference herein in their entireties.

### BACKGROUND

### 1. Field

Embodiments relate to an image sensor.

### 2. Description of the Related Art

Image sensors are devices that convert an optical image into an electrical signal. In recent years, with the development of the computer industry and the communication industry, demands for image sensors with improved performance are increasing in various fields such as digital cameras, camcorders, personal communication systems (PCSs), game devices, security cameras, medical micro cameras, robots, and the like. In particular, demands for CMOS image sensors (CISs) mounted in home appliances including portable devices, such as smart phones, digital cameras and the like, are increasing.

### SUMMARY

Embodiments are directed to a semiconductor device, including a gate electrode, a first region under the gate electrode and extending from a first direction to a second direction crossing the first direction, the first region having a bent shape, a first source-drain region extending from one end of the first region, a second source-drain region extending from an opposite end of the first region, and a third source-drain region at a point where a first virtual straight line extending from the first source-drain region in the first direction and a second virtual straight line extending from the second source-drain region in a direction opposite to the second direction cross each other in the first region, wherein the third source-drain region forms a first channel region together with the first source-drain region and forms a second channel region together with the second source-drain region.

Embodiments are directed to a semiconductor device, including a gate electrode, a first channel region extending in a first direction under the gate electrode, a first source-drain region and a second source-drain region at opposite ends of the first channel region, a second channel region extending in a second direction crossing the first direction from the second source-drain region, a third source-drain region at an opposite end of the second channel region, a third channel region extending in the second direction from the third source-drain region, a fourth source-drain region at an opposite end of the third channel region, a fourth channel region extending in a direction opposite to the first direction from the fourth source-drain region, and a fifth source-drain region at an opposite end of the fourth channel region, wherein the second source-drain region, the third source-drain region, and the fourth source-drain region have a third width smaller than a first width of the first source-drain region and a second width of the fifth source-drain region.

Embodiments are directed to an image sensor, including a photo diode configured to generate electric charges in response to incident light, a drive transistor configured to generate a source-drain current depending on the incident light, based on an output of the photo diode, a transfer transistor configured to transfer the output of the photo diode to the drive transistor, and a device isolation pattern configured to isolate the drive transistor from a ground, wherein the drive transistor includes a gate electrode, a first channel region extending in a first direction under the gate electrode, a first source-drain region and a third source-drain region at opposite ends of the first channel region, a second channel region extending in a second direction crossing the first direction from the third source-drain region, and a second source-drain region at an opposite end of the second channel region, and at least a portion of the first channel region and at least a portion of the second channel region are spaced apart from the device isolation pattern.

### BRIEF DESCRIPTION OF THE FIGURES

Features will become apparent to those of skill in the art by describing in detail exemplary embodiments with reference to the attached drawings in which:

FIG. 1 is a block diagram of an image sensor according to an embodiment of the present disclosure;

FIG. 2 is a circuit diagram of a unit pixel included in a pixel array of FIG. 1;

FIG. 3 shows a layout for a unit pixel included in the pixel array of FIG. 1;

FIG. 4 shows a layout of a semiconductor device 200A according to an embodiment of the present disclosure;

FIG. 5A shows a sectional view of the semiconductor device taken along line A-A′ in FIG. 4;

FIG. 5B is a circuit diagram of the semiconductor device of FIG. 4;

FIG. 6A shows a plan view of region B under a gate electrode of the semiconductor device of FIG. 4;

FIG. 6B shows a plan view of region C under the gate electrode of the semiconductor device of FIG. 4;

FIG. 7 shows a layout of a semiconductor device 200B according to another embodiment of the present disclosure;

FIG. 8A shows a sectional view of the semiconductor device taken along line b-b′ in FIG. 7;

FIG. 8B shows a plan view of region D under a gate electrode of the semiconductor device of FIG. 7;

FIG. 9 shows a layout of a semiconductor device 200C according to another embodiment of the present disclosure;

FIG. 10A shows a sectional view of the semiconductor device taken along line a-a′ in FIG. 9;

FIG. 10B shows a sectional view of the semiconductor device taken along line D-D′ in FIG. 9;

FIG. 11A shows a plan view of region b under a gate electrode of the semiconductor device of FIG. 9;

FIG. 11B shows a plan view of region c under the gate electrode of the semiconductor device of FIG. 9;

FIG. 12 shows a layout of a semiconductor device 200D according to another embodiment of the present disclosure; and

FIG. 13 shows a sectional view of the semiconductor device taken along line c-c′ in FIG. 12.

### DETAILED DESCRIPTION

Hereinafter, embodiments of the present disclosure will be described clearly and in detail to such an extent that those skilled in the art easily implement the present disclosure.

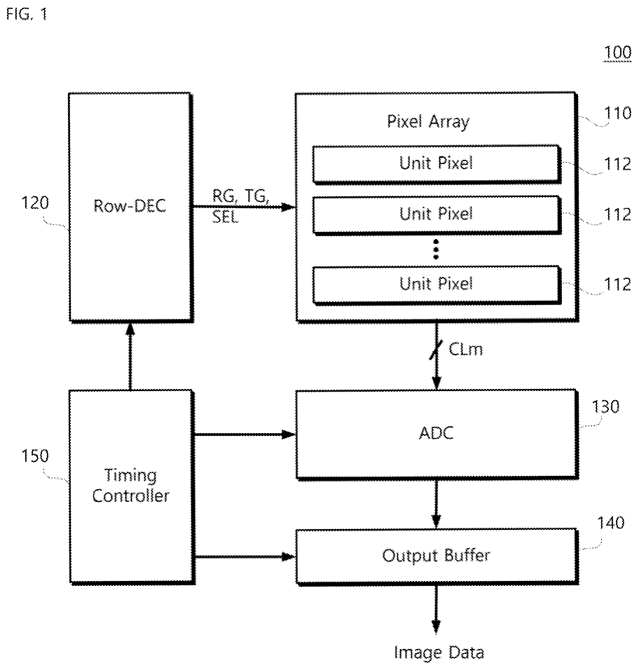

FIG. 1 is a block diagram of an image sensor according to an embodiment of the present disclosure.

Referring to FIG. 1, the image sensor 100 may include a pixel array 110, a row-DEC 120, an analog-to-digital converter (ADC) 130, an output buffer 140, and a timing controller 150.

The pixel array 110 according to an embodiment may include a plurality of unit pixels 112. The plurality of unit pixels 112 may be arranged, e.g., in a matrix form.

The pixel array 110 may receive sensor drive signals, such as a selection signal SEL, a reset signal RG, and a transmission signal TG, from the row-DEC 120. The pixel array 110 may operate under the control of the received sensor drive signals.

In an implementation, each of the unit pixels 112 included in the pixel array 110 may convert a light signal into an electrical signal. The electrical signals generated by the unit pixels 112 may be provided to the analog-to-digital converter 130 through a plurality of column lines CLm.

Each of the unit pixels 112 may include a drive transistor implemented through a region having a bent shape. Through this configuration, the image sensor 100 according to the present disclosure may increase a channel area of the drive transistor, thereby minimizing noise of an electrical signal.

The row-DEC 120 may select any one row of the pixel array 110 under the control of the timing controller 150. In an implementation, the row-DEC 120 may generate the selection signal SEL to select one of a plurality of rows.

In addition, the row-DEC 120 may activate the reset signal RG and the transmission signal TG in a predetermined sequence for unit pixels 112 corresponding to the selected row.

However, according to another embodiment, the row-DEC 120 may simultaneously activate the reset signal RG for all of the unit pixels 112 of the pixel array 110. In this case, all of the unit pixels 112 of the pixel array 110 may be simultaneously reset. Furthermore, the rest unit pixels 112 may accumulate photo charges through a photo diode.

Thereafter, a reset level signal and a sensing signal generated from each of the unit pixels 112 of the pixel array 110 may be transferred to the analog-to-digital converter 130.

The analog-to-digital converter 130 may convert the reset level signal and the sensing signal input from the pixel array 110 into digital signals and may output the digital signals. In an implementation, the analog-to-digital converter 130 may sample the reset level signal and the sensing signal by a correlated double sampling method and thereafter may convert the reset level signal and the sensing signal into digital signals. To this end, a correlated double sampler (CDS) may be additionally disposed at a front end of the analog-to-digital converter 130.

The output buffer 140 may latch and output image data in units of columns provided by the analog-to-digital converter 130. The output buffer 140 may temporarily store the image data output from the analog-to-digital converter 130 under the control of the timing controller 150 and thereafter may output image data sequentially latched by a column decoder.

The timing controller 150 may control at least a part of the pixel array 110, the row-DEC 120, the analog-to-digital converter (ADC) 130, and the output buffer 140. The timing controller 150 may supply control signals, such as a clock signal, a timing control signal, and the like, for operations of the pixel array 110, the row-DEC 120, the analog-to-digital converter (ADC) 130, and the output buffer 140. The timing controller 150 may include at least one of a logic control circuit, a phase lock loop (PLL) circuit, a timing control circuit, or a communication interface circuit.

The configuration of the image sensor 100 according to the embodiment of the present disclosure has been described above in brief Hereinafter, a more specific configuration of the unit pixel 112 implemented to minimize noise will be described.

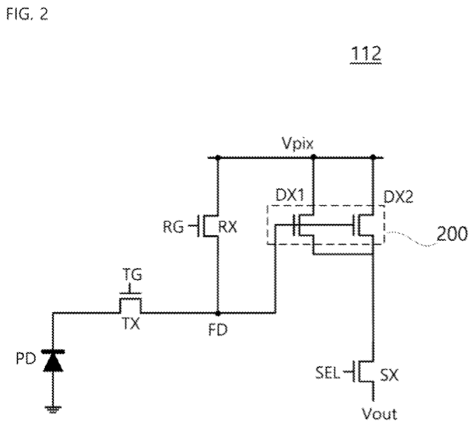

FIG. 2 is a circuit diagram of a unit pixel included in the pixel array of FIG. 1.

Referring to FIG. 2, the unit pixel 112 may include one photo diode PD and five transistors TX, RX, DX1, DX2, and SX. In an implementation, the unit pixel 112 may include the photo diode PD, the transfer transistor TX, the reset transistor RX, the drive transistor DX1 and DX2, and the selection transistor SX.

The photo diode PD according to an embodiment may generate and accumulate electric charges depending on the amount or intensity of incident light.

The photo diode PD may be referred to as a light sensing element implemented with a photo transistor, a photo gate, a pinned photo diode (PPD), an organic photo diode (OPD), a quantum dot (QD), or the like.

The transfer transistor TX may be turned on or off in response to the transmission signal TG provided from the row-DEC 120. The transfer transistor TX may transmit the electric charges accumulated in the photo diode PD to a floating diffusion region FD.

To this end, a drain of the transfer transistor TX may be connected with the photo diode PD. In addition, a source of the transfer transistor TX may be connected with the floating diffusion region FD.

The floating diffusion region FD may be connected to the source of the transfer transistor TX, a source of the reset transistor RX, and a gate of the drive transistor DX.

The reset transistor RX may be turned on or off in response to the reset signal RG. In an implementation, the reset transistor RX may be turned on depending on the reset signal RG and may apply a reset voltage to the gate of the drive transistor DX.

In an implementation, the reset transistor RX may be turned on in response to activation of the reset signal RG, and a power supply voltage Vpix may be transferred to the floating diffusion region FD. At this time, the voltage of the floating diffusion region FD may be reset to the level of the power supply voltage Vpix.

To this end, a drain of the reset transistor RX may be connected with the power supply voltage Vpix. In addition, the source of the reset transistor RX may be connected to the floating diffusion region FD.

The drive transistor 200 may generate a source-drain current depending on the magnitude of photo charges applied to the gate. In an implementation, the drive transistor 200 may generate a source-drain current proportional to the magnitude of photo charges applied to the gate from the floating diffusion region FD.

To this end, the gate of the drive transistor 200 may be connected to the floating diffusion region FD. In addition, a drain of the drive transistor 200 may be connected with the power supply voltage Vpix.

The drive transistor 200 may serve as a source follower amplifier. In an implementation, the drive transistor 200 may amplify a potential change of the floating diffusion region FD. In addition, the drive transistor 200 may output the amplified potential change via the selection transistor SX.

According to an embodiment, the drive transistor 200 may be implemented through a region having a bent shape. The drive transistor 200 may include the first transistor DX1 and the second transistor DX2.

In an implementation, the drive transistor 200 may include the first transistor DX1 and the second transistor DX2 that include channels formed in different directions in the bent shape.

Drains of the first transistor DX1 and the second transistor DX2 may be connected with the power supply voltage Vpix and may be connected in parallel.

Through the above-described configuration, the unit pixel 112 may include the drive transistor 200 having an increased channel width.

The selection transistor SX may be used to select unit pixels that are to be read in units of rows. The selection transistor SX may be driven by the selection signal SEL provided in units of rows. When the selection transistor SX is turned on, the potential of the floating diffusion region FD may be amplified and transferred to a drain of the selection transistor SX through the drive transistor 200.

As described above, photo charges generated through the photo diode PD may be output as image data through the transfer transistor TX, the floating diffusion region FD, the drive transistor 200, and the selection transistor SX.

The image sensor 100 according the embodiment of the present disclosure may include the drive transistor 200, the channel width of which is increased, and thus may reduce noise of an output signal Vout.

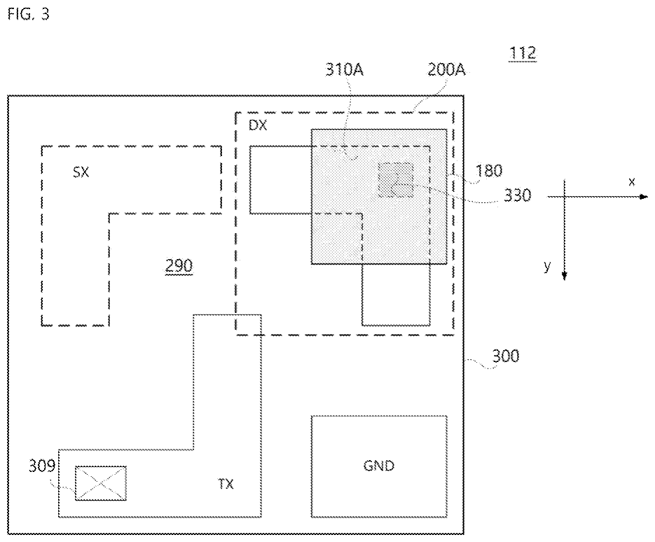

FIG. 3 shows a layout for a unit pixel included in the pixel array of FIG. 1.

Referring to FIG. 3, the unit pixel 112 of the pixel array 110 according to an embodiment may include a transfer transistor TX, a semiconductor device 200A, a selection transistor SX, and a ground GND in a rectangular cell 300.

The semiconductor device 200A may be understood as an example of the drive transistor 200 of FIG. 2. In an implementation, the semiconductor device 200A, as an example of the drive transistor 200 of FIG. 2, may be understood as a transistor including source-drain regions formed in a first region 310A having a bent shape.

However, the unit pixel 112 may not include some of the components (e.g., the selection transistor SX), or may additionally include other components (e.g., the photo diode PD or the reset transistor RX of FIG. 2).

The unit pixel 112 may include a device isolation pattern 290 formed between the semiconductor device 200A, the transfer transistor TX, the selection transistor SX, and the ground 280. The device isolation pattern 290 may be understood as an insulating structure for electrically isolating the semiconductor device 200A from the ground GND or other transistors in the cell 300.

In an implementation, the device isolation pattern 290 may be formed through a shallow trench isolation (STI) process. In another implementation, the device isolation pattern 290 may be formed through a deep trench isolation (DTI) process.

In addition, e.g., the device isolation pattern 290 may be formed of an oxide and/or polysilicon.

The selection transistor SX may be driven by the selection signal SEL. In an implementation, the selection transistor SX may output a signal transferred from the semiconductor device 200A, based on the selection signal SEL.

The transfer transistor TX may transfer photo charges transferred from the photo diode PD to the semiconductor device 200A. In an implementation, the transfer transistor TX may transfer the photo charges transferred from the photo diode PD to the semiconductor device 200A through a contact 309 adjacent to the floating diffusion region FD. The floating diffusion region FD may be electrically connected with the semiconductor device 200A through the contact 309.

The transfer transistor TX may be referred to as a vertical transfer transistor. In an implementation, the transfer transistor TX may include a vertical transfer gate (VTG).

A portion of the vertical transfer gate VTG may extend into the cell 300. The vertical transfer gate VTG may include a lower portion inserted into the cell 300 and an upper portion extending from the lower portion and protruding from the cell 300. Through this configuration, the image sensor 100 may reduce the area of the unit pixel 112.

The semiconductor device 200A may receive a voltage from the floating diffusion region FD through the above-described electrical connection using the contact 309.

According to an embodiment, the semiconductor device 200A may include a gate electrode 180 and the first region 310A that is formed under the gate electrode 180 and that has a bent shape. In an implementation, the semiconductor device 200A may include the first region 310A extending from a first direction (e.g., the +x direction) to a second direction (e.g., the +y direction) crossing the first direction and having a bent shape.

The semiconductor device 200A may further include a source-drain region 330 formed in the first region 310A.

As described above, the unit pixel 112 according to the embodiment may include the semiconductor device 200A formed through the first region 310A having a bent shape and the source-drain region 330 formed in the first region 310A.

Accordingly, the image sensor 100 according to the embodiment of the present disclosure may increase the area of a channel of the semiconductor device 200A within the limited area of the unit pixel 112. In addition, the image sensor 100 may reduce noise included in an output signal of the semiconductor device 200A.

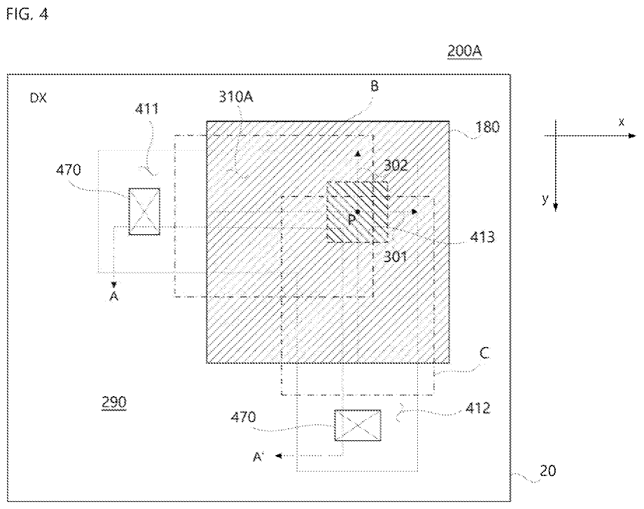

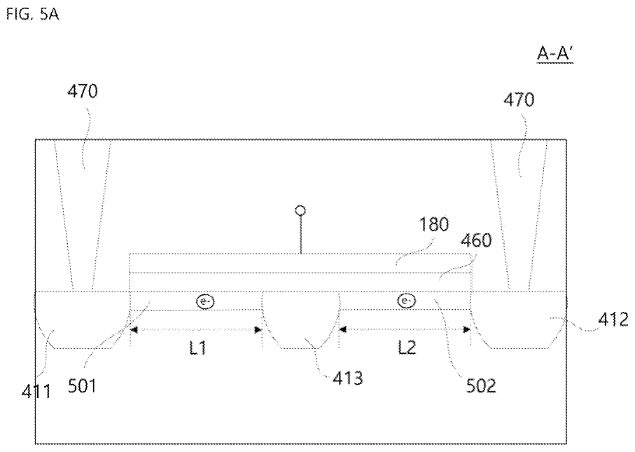

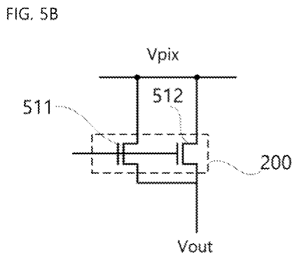

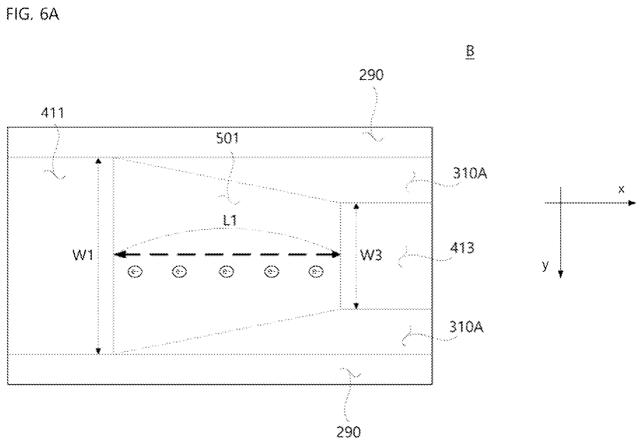

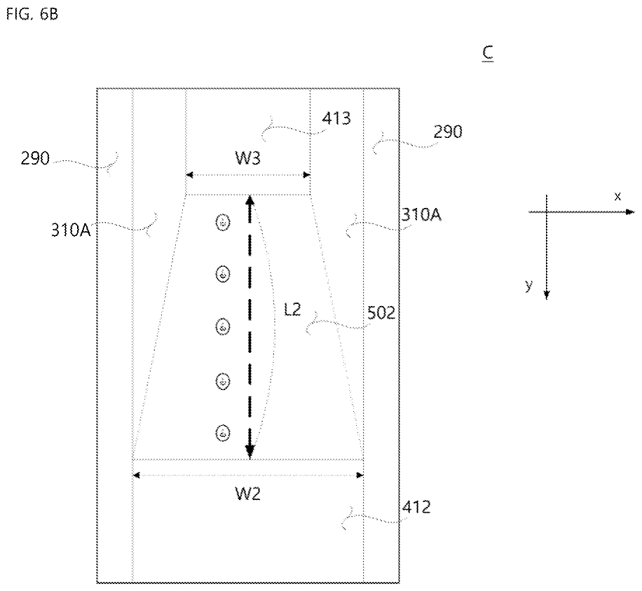

FIG. 4 shows a layout of the semiconductor device 200A according to an embodiment of the present disclosure. FIG. 5A shows a sectional view of the semiconductor device taken along line A-A′ in FIG. 4. FIG. 5B is a circuit diagram of the semiconductor device of FIG. 4. FIG. 6A shows a plan view of region B under the gate electrode of the semiconductor device of FIG. 4. FIG. 6B shows a plan view of region C under the gate electrode of the semiconductor device of FIG. 4.

Referring to FIGS. 4 to 6B together, the semiconductor device 200A according to an embodiment may include a substrate 20, the gate electrode 180, the first region 310A formed under the gate electrode 180, and a first source-drain region 411 and a second source-drain region 412 formed at opposite ends of the first region 310A.

The substrate 20 according to an embodiment may be understood as a semiconductor substrate. In an implementation, the substrate 20 may include silicon, strained Si, silicon alloy, silicon carbide (SiC), silicon germanium (SiGe), silicon germanium carbide (SiGeC), germanium, germanium alloy, gallium arsenide (GaAs), indium arsenide (InAs), III-V semiconductor, II-VI semiconductor, or a combination or laminate thereof. Furthermore, a substrate 20 according to another embodiment may be understood as an organic plastic substrate rather than a semiconductor substrate.

The device isolation pattern 290 may be formed on the substrate 20 so as to be adjacent to at least a part of the first region 310A, the first source-drain region 411, and the second source-drain region 412. The device isolation pattern 290 may electrically isolate the first region 310A, the first source-drain region 411, and the second source-drain region 412 from another device or region (e.g., the ground 280) on the substrate 20.

The first region 310A may be formed under the gate electrode 180. In an implementation, under the gate electrode 180, the first region 310A may extend from the first direction (e.g., the +x direction) to the second direction (e.g., the +y direction) crossing the first direction and may have a bent shape.

In an implementation, the first direction and the second direction may be perpendicular to each other. Accordingly, the first region 310A may have a shape bent at a right angle.

According to an embodiment, the semiconductor device 200A may include the first source-drain region 411 formed at one end of the first region 310A and the second source-drain region 412 formed at an opposite end of the first region 310A.

In an implementation, the semiconductor device 200A may include the first source-drain region 411 extending from the one end of the first region 310A in a direction (e.g., the −x direction) opposite to the first direction. Furthermore, the semiconductor device 200A may include the second source-drain region 412 extending from the opposite end of the first region 310A in the second direction (e.g., the +y direction).

In addition, the semiconductor device 200A may include a third source-drain region 413 formed in the first region 310A. The third source-drain region 413 may be understood as the source-drain region 330 of FIG. 3.

In an implementation, the semiconductor device 200A according to an embodiment may include the third source-drain region 413 formed at a point P where a first virtual straight line 301 extending from the first source-drain region 411 in the first direction and a second virtual straight line 302 extending from the second source-drain region 412 in a direction (e.g., the −y direction) opposite to the second direction cross each other in the first region 310A. In an implementation, the third source-drain region 413 may have the point P where the first virtual straight line 301 and the second virtual straight line 302 cross each other as the center thereof. In an implementation, the third source-drain region 413 may be formed to include the point P where the first virtual straight line 301 and the second virtual straight line 302 cross each other.

According to another embodiment, the semiconductor device 200A may include a third source-drain region 413 formed in a region bent from the first direction to the second direction in the first region 310A. In an implementation, the third source-drain region 413 may be formed in a region where a first sub-region formed in the first direction and a second sub-region formed in the second direction overlap each other in the first region 310A.

According to another embodiment, the semiconductor device 200A may include a third source-drain region 413 formed in the first region 310A so as to be spaced apart from the periphery of the first region 310A.

Referring to FIGS. 4 and 5A together, the third source-drain region 413 and the first source-drain region 411 may form a first channel region 501 under the gate electrode 180. Furthermore, the third source-drain region 413 and the second source-drain region 412 may form a second channel region 502 under the gate electrode 180.

In FIG. 5A, the first source-drain region 411, the second source-drain region 412, and the third source-drain region 413 are shown as having a rounded quadrangular cross-section. In another implementation, the first source-drain region 411, the second source-drain region 412, and the third source-drain region 413 may have a tapered cross-section, or may have a quadrangular cross-section.

A gate insulating layer 460 according to an embodiment may be formed on the first region 310A. The gate insulating layer 460 may be formed under the gate electrode 180. The gate insulating layer 460 may be formed of a high-k material. In an implementation, the gate insulating layer 460 may be formed of a material such as HfO₂, Al₂O₃, ZrO₂, TaO₂, or the like.

The gate electrode 180 may be on the gate insulating layer 460. The gate electrode 180 may include a conductive material. In an implementation, the gate electrode 180 may be formed of poly silicon. In another implementation, the gate electrode 180 may include highly conductive metal.

In FIG. 5A, the gate electrode 180 and the gate insulating layer 460 are shown as being formed in a region overlapping the third source-drain region 413, the first channel region 501, and the second channel region 502 when viewed from above the gate electrode 180.

According to an embodiment, the gate electrode 180 and the gate insulating layer 460 may be formed on the first channel region 501 and the second channel region 502.

In an implementation, the gate electrode 180 and the gate insulating layer 460, when viewed from above the gate electrode 180, may be formed in a region other than the region overlapping the third source-drain region 413. That is, the gate electrode 180 and the gate insulating layer 460, when viewed from above the gate electrode 180, may be formed in a region overlapping the first channel region 501 and the second channel region 502.

According to an embodiment, the first channel region 501 may have a first channel length L1. Furthermore, the second channel region 502 may have a second channel length L2.

Accordingly, the semiconductor device 200A may be understood as a transistor having a channel length L1+L2 obtained by adding the first channel length L1 of the first channel region 501 and the second channel length L2 of the second channel region 502.

Through the above-described structure, the image sensor 100 (or, the unit pixel 112) according to the embodiment of the present disclosure may increase the channel length of the drive transistor 200. In addition, the image sensor 100 may reduce noise included in an output signal.

Referring to FIGS. 4 to 5B, the third source-drain region 413 may form a first transistor 511 together with the first source-drain region 411 and the gate electrode 180. Furthermore, the third source-drain region 413 may form a second transistor 512 together with the second source-drain region 412 and the gate electrode 180.

In an implementation, the first source-drain region 411 and the second source-drain region 412 may be referred to as a drain region of the first transistor 511 and a drain region of the second transistor 512, respectively. Furthermore, the third source-drain region 413 may be referred to as a source region of the first transistor 511 or a source region of the second transistor 512.

However, the distinction of the first source-drain region 411, the second source-drain region 412, and the third source-drain region 413 (e.g., a source region or a drain region) may be changed as needed.

The semiconductor device 200A may further include source-drain contacts 470 on the first source-drain region 411 and the second source-drain region 412.

The first source-drain region 411 and the second source-drain region 412 may be electrically connected through the source-drain contacts 470. The first transistor 511 and the second transistor 512 may be connected together to the power supply voltage Vpix and the gate electrode 180.

That is, the first transistor 511 and the second transistor 512 may be connected in parallel.

Accordingly, the semiconductor device 200A (or, the drive transistor 200) according to the embodiment of the present disclosure may be understood as including the two transistors 511 and 512 connected in parallel.

According to the above description, the semiconductor device 200A according to the embodiment may be understood as a transistor having a channel width obtained by adding the channel width of the first transistor 511 and the channel width of the second transistor 512.

Accordingly, the image sensor 100 according to the embodiment of the present disclosure may increase the channel width of the drive transistor 200. Thus, the image sensor 100 may reduce noise included in an output signal of the drive transistor 200.

Furthermore, the first transistor 511 and the second transistor 512 according to the embodiment may be formed through the single gate electrode 180. Accordingly, the image sensor 100 according to the embodiment of the present disclosure may not include a metal line for connection between a plurality of gates. In addition, the image sensor 100 may minimize parasitic capacitance due to the metal line between the gates.

Referring to FIGS. 6A and 6B together, the semiconductor device 200A according to an embodiment may include the first channel region 501 formed in the first direction (e.g., the x direction) under the gate electrode 180. Furthermore, the semiconductor device 200A may include the first source-drain region 411 and the third source-drain region 413 formed at opposite ends of the first channel region 501.

Moreover, the semiconductor device 200A may include the second channel region 502 formed in the second direction (e.g., the y direction) crossing the first direction from the third source-drain region 413. In addition, the semiconductor device 200A may include the second source-drain region 412 formed at one end of the second channel region 502.

According to an embodiment, the third source-drain region 413 may have a third width W3 smaller than a first width W1 of the first source-drain region 411 and a second width W2 of the second source-drain region 412. Furthermore, at least a portion of the third source-drain region 413 may be formed to be spaced apart from the periphery of the first region 310A.

In an implementation, referring to FIG. 6A, the first source-drain region 411 may have the first width W1 corresponding to the width of the one end of the first region 310A. The third source-drain region 413 may have the third width W3 smaller than the first width W1 of the first source-drain region 411.

Accordingly, the third source-drain region 413 and the first source-drain region 411 may form the first channel region 501 at least partially spaced apart from the device isolation pattern 290. The first channel region 501 may have the first channel length L1 and may be formed in the first direction (e.g., the x direction).

In an implementation, a source-drain current may be generated along a path spaced apart from the device isolation pattern 290 in the first channel region 501 in response to application of a voltage to the gate electrode 180.

Referring to FIG. 6B, the second source-drain region 412 may have the second width W2 corresponding to the width of the opposite end of the first region 310A. The third source-drain region 413 may have the third width W3 smaller than the second width W2 of the second source-drain region 412.

Accordingly, the third source-drain region 413 and the second source-drain region 412 may form the second channel region 502 at least partially spaced apart from the device isolation pattern 290. The second channel region 502 may have the second channel length L2 and may be formed in the second direction (e.g., the y direction).

In an implementation, a source-drain current may be generated along a path spaced apart from the device isolation pattern 290 in the second channel region 502 in response to application of a voltage to the gate electrode 180.

Through the above-described configuration, the semiconductor device 200A may include the channel regions formed to be at least partially spaced apart from the device isolation pattern 290.

Accordingly, the image sensor 100 according to the embodiment of the present disclosure may prevent (or, minimize) charge trapping that occurs in a region adjacent to the device isolation pattern 290 among the channels (or, the channel regions) of the transistor. In addition, the image sensor 100 may reduce noise generated due to the charge trapping in the drive transistor 200.

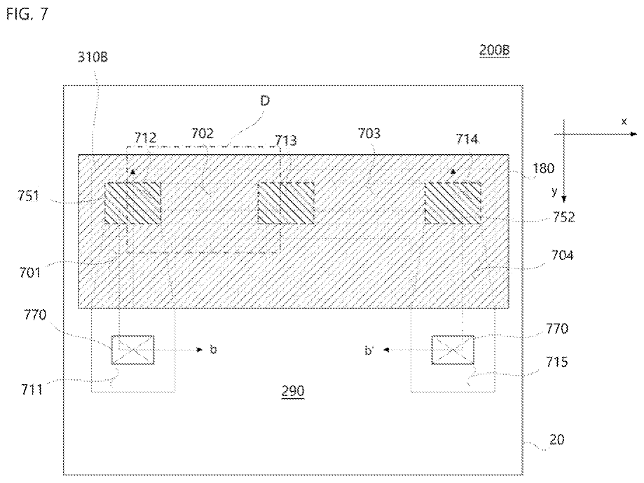

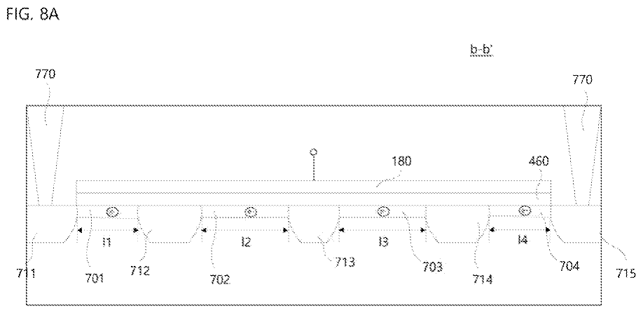

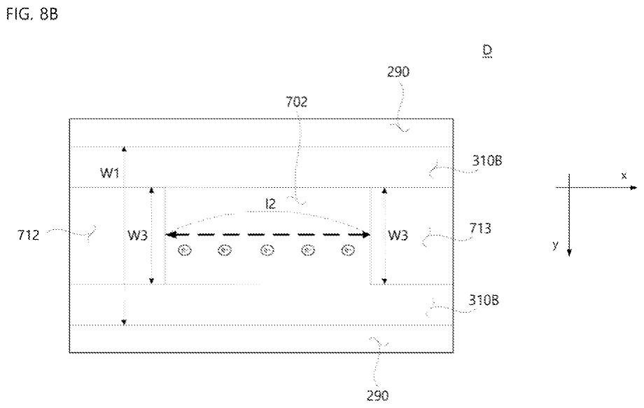

FIG. 7 shows a layout of a semiconductor device 200B according to another embodiment of the present disclosure. FIG. 8A shows a sectional view of the semiconductor device taken along line b-b′ in FIG. 7. FIG. 8B shows a plan view of region D under a gate electrode of the semiconductor device of FIG. 7.

Referring to FIGS. 7 to 8B together, the semiconductor device 200B according to an embodiment may include a substrate 20, the gate electrode 180, a first region 310B formed under the gate electrode 180, and a first source-drain region 711 and a fifth source-drain region 715 formed at opposite ends of the first region 310B.

The semiconductor device 200B of FIG. 7 may be understood as an example of the drive transistor 200 of FIG. 2. Therefore, components that are the same as, or substantially the same as, the above-described components will be assigned with the same reference numerals, and repetitive descriptions will be omitted.

The first region 310B may be formed under the gate electrode 180. The first region 310B may have a bent shape under the gate electrode 180.

In an implementation, the first region 310B may extend from the direction (e.g., the −y direction) opposite to the second direction to the first direction (e.g., the +x direction) crossing the second direction and from the first direction to the second direction (e.g., the +y direction) and may have a bent shape. The first region 310B may be understood as having a shape bent to have two corners.

In an implementation, the first direction and the second direction may be perpendicular to each other. Accordingly, the first region 310B may have a shape bent twice at a right angle. That is, the first region 310B may have a quadrangular shape, one side of which is open.

According to an embodiment, the semiconductor device 200B may include the first source-drain region 711 extending from one end of the first region 310B in the second direction (e.g., the +y direction). Furthermore, the semiconductor device 200B may include the fifth source-drain region 715 extending from an opposite end of the first region 310B in the second direction.

In addition, the semiconductor device 200B may include a second source-drain region 712, a third source-drain region 713, and a fourth source-drain region 714 that are formed in the first region 310B.

In an implementation, the first region 310B may include a first channel region 701 adjacent to the first source-drain region 711 and formed in the direction (e.g., the −y direction) opposite to the second direction. The first region 310B may include the second source-drain region 712 formed at one end of the first channel region 701.

The first region 310B may include a second channel region 702 formed in the first direction (e.g., the +x direction) from the second source-drain region 712. The first region 310B may include the third source-drain region 713 formed at one end of the second channel region 702.

The first region 310B may include a third channel region 703 formed in the first direction from the third source-drain region 713. The first region 310B may include the fourth source-drain region 714 formed at one end of the third channel region 703.

The first region 310B may include a fourth channel region 704 formed in the second direction (e.g., the +y direction) from the fourth source-drain region 714. One end of the fourth channel region 704 may be connected with the fifth source-drain region 715.

According to another embodiment, the semiconductor device 200B may include the second source-drain region 712 formed in a region bent from the direction opposite to the second direction to the first direction in the first region 310B. In an implementation, the second source-drain region 712 may be formed in a region where a first sub-region formed in the direction opposite to the second direction and a second sub-region formed in the first direction overlap each other in the first region 310B.

Furthermore, the semiconductor device 200B may include the fourth source-drain region 714 formed in a region bent from the first direction to the second direction in the first region 310B. In an implementation, the fourth source-drain region 714 may be formed in a region where the second sub-region formed in the first direction and a third sub-region formed in the second direction overlap each other in the first region 310B.

The semiconductor device 200B may include the third source-drain region 713 formed between the second source-drain region 712 and the fourth source-drain region 714 in the first region 310B.

According to another embodiment, the semiconductor device 200B may include the second source-drain region 712, the third source-drain region 713, and the fourth source-drain region 714 that are formed in the first region 310B so as to be spaced apart from the periphery of the first region 310.

According to an embodiment, each of the above-described source-drain regions (the first to fifth source-drain regions 711 to 715) may form a transistor together with an adjacent source-drain region and the gate electrode 180. In an implementation, the second source-drain region 712 may form a transistor together with the third source-drain region 713 and the gate electrode 180. The third source-drain region 713 may form a transistor together with the fourth source-drain region 714 and the gate electrode 180.

In an implementation, the second source-drain region 712 and the fourth source-drain region 714 may be referred to as source regions of the transistors, respectively. The first source-drain region 711, the third source-drain region 713, and the fifth source-drain region 715 may be referred to as drain regions of transistors, respectively.

However, the distinction of the first source-drain region 711, the second source-drain region 712, the third source-drain region 713, the fourth source-drain region 714, and the fifth source-drain region 715 (e.g., a source region or a drain region) may be changed as needed.

According to an embodiment, the semiconductor device 200B may further include source-drain contacts 770 on the first source-drain region 711 and the fifth source-drain region 715. The first source-drain region 711 and the fifth source-drain region 715 may be electrically connected through the source-drain contacts 770.

The second source-drain region 712, the third source-drain region 713, and the fourth source-drain region 714 may be electrically connected.

Accordingly, the transistors formed by the above-described source-drain regions may be connected in parallel. Thus, the semiconductor device 200B according to the present disclosure may include the plurality of transistors connected in parallel. As a result, the semiconductor device 200B according to the present disclosure may increase the channel width of the transistor through the configuration in which the plurality of transistors are connected in parallel.

Referring to FIGS. 7 and 8A, the gate electrode 180 and a gate insulating layer 460 are shown as being formed in a region overlapping the second source-drain region 712, the third source-drain region 713, the fourth source-drain region 714, the first channel region 701, the second channel region 702, the third channel region 703, and the fourth channel region 704 when viewed from above the gate electrode 180.

According to another embodiment, the gate electrode 180 and the gate insulating layer 460 may be formed on the first channel region 701, the second channel region 702, the third channel region 703, and the fourth channel region 704.

In an implementation, the gate electrode 180 and the gate insulating layer 460, when viewed from above the gate electrode 180, may be formed in a region other than the regions overlapping the second source-drain region 712, the third source-drain region 713, and the fourth source-drain region 714. That is, the gate electrode 180 and the gate insulating layer 460, when viewed from above the gate electrode 180, may be formed in a region overlapping the first channel region 701, the second channel region 702, the third channel region 703, and the fourth channel region 704.

In FIG. 8A, the first source-drain region 711, the second source-drain region 712, the third source-drain region 713, the fourth source-drain region 714, and the fifth source-drain region 715 are shown as having a rounded quadrangular cross-section.

According to an embodiment, the first channel region 701 may have a first channel length l1. The second channel region 702 may have a second channel length l2. The third channel region 703 may have a third channel length l3. The fourth channel region 704 may have a fourth channel length l4.

Accordingly, the semiconductor device 200B may be understood as a transistor having a channel length l1+l2+l3+l4 obtained by adding the channel lengths l1 to l4 of the first to fourth channel regions 701 to 704.

Through the above-described structure, the image sensor 100 (or, the unit pixel 112) according to the embodiment of the present disclosure may increase the channel length of the drive transistor 200. In addition, the image sensor 100 may reduce noise included in an output signal.

The first channel region 701 and the fourth channel region 704 according to an embodiment may be understood as having the same structure as the first channel region 501 and the second channel region 502 of FIGS. 6A and 6B. Therefore, in description of the first channel region 701 and the fourth channel region 704, contents identical with the above-described ones will be omitted.

Referring to FIGS. 7 and 8B together, the semiconductor device 200B may include the second channel region 702 and the third channel region 703 that are formed in the first direction (e.g., the x direction) under the gate electrode 180.

The second source-drain region 712, the third source-drain region 713, and the fourth source-drain region 714 may have a third width W3 smaller than a first width W1 of the first region 310B. Alternatively, the second source-drain region 712, the third source-drain region 713, and the fourth source-drain region 714 may have the third width W3 smaller than the widths of the first source-drain region 711 and the fifth source-drain region 715 (e.g., the first width W1).

At least a portion of the second source-drain region 712, at least a portion of the third source-drain region 713, and at least a portion of the fourth source-drain region 714 may be spaced apart from the periphery of the first region 310B.

Referring to FIG. 8B, the second source-drain region 712 and the third source-drain region 713 may form the second channel region 702 at least partially spaced apart from the device isolation pattern 290. The second channel region 702 may have the second channel length l2 and may be formed in the first direction (e.g., the x direction).

According to an embodiment, a source-drain current may be generated along a path spaced apart from the device isolation pattern 290 in the second channel region 702 in response to application of a voltage to the gate electrode 180.

The third source-drain region 713 and the fourth source-drain region 714 may form the third channel region 703 corresponding to the second channel region 702.

According to an embodiment, a source-drain current may be generated along a path spaced apart from the device isolation pattern 290 in the third channel region 703 in response to application of a voltage to the gate electrode 180.

Through the above-described configuration, the semiconductor device 200B may have the channel regions (or, the current paths) at least partially spaced apart from the device isolation pattern 290.

Accordingly, the image sensor 100 according to the embodiment of the present disclosure may prevent (or, minimize) charge trapping that occurs in a region adjacent to the device isolation pattern 290 among the channels (or, the channel regions) of the transistor. In addition, the image sensor 100 may reduce noise generated due to the charge trapping in the drive transistor 200.

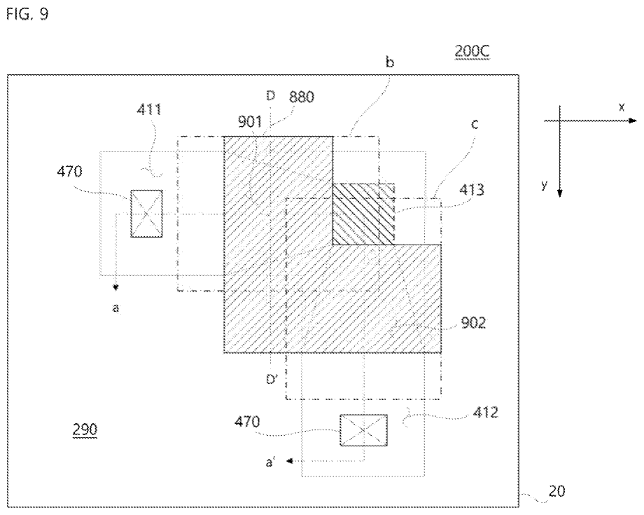

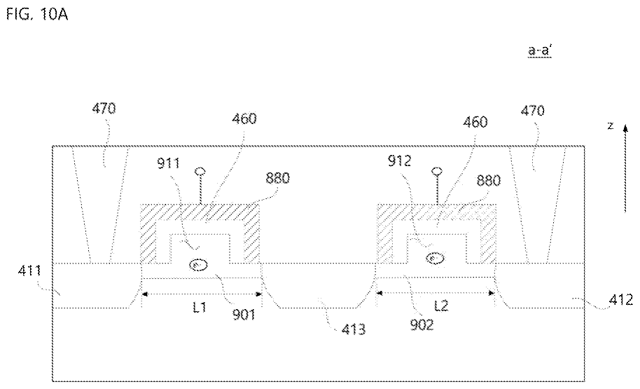

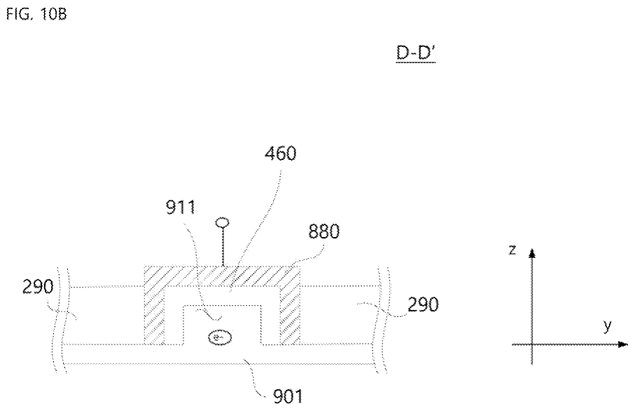

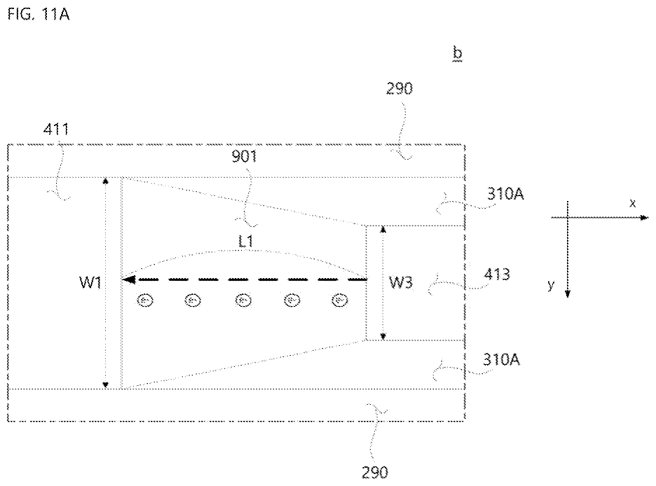

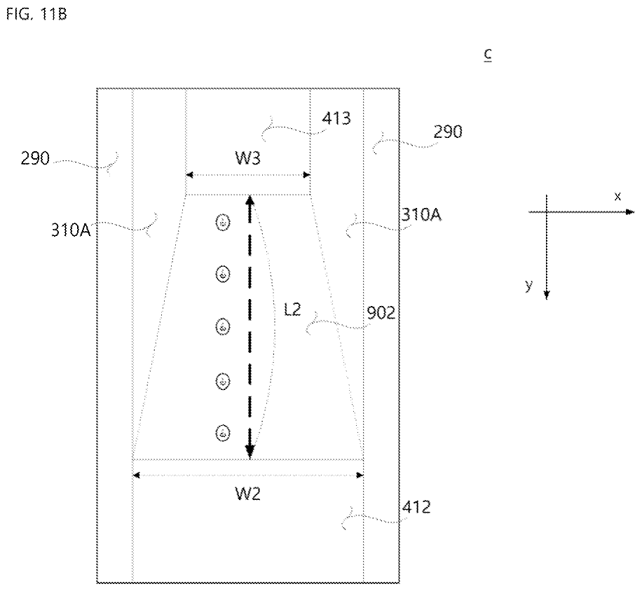

FIG. 9 shows a layout of a semiconductor device 200C according to another embodiment of the present disclosure. FIG. 10A shows a sectional view of the semiconductor device taken along line a-a′ in FIG. 9. FIG. 10B shows a sectional view of the semiconductor device taken along line D-D′ in FIG. 9. FIG. 11A shows a plan view of region b under a gate electrode of the semiconductor device of FIG. 9. FIG. 11B shows a plan view of region c under the gate electrode of the semiconductor device of FIG. 9.

Referring to FIG. 9, the semiconductor device 200C according to an embodiment may include the gate electrode 880, and a first channel region 901 and a second channel region 902 that are formed under the gate electrode 880.

The semiconductor device 200C may be understood as an example of the drive transistor 200 of FIG. 2. Therefore, components that are the same as, or substantially the same as, the above-described components will be assigned with the same reference numerals, and repetitive descriptions will be omitted.

The first channel region 901 may be formed in the first direction (e.g., the +x direction) under the gate electrode 880. A first source-drain region 411 and a third source-drain region 413 may be formed at opposite ends of the first channel region 901.

The second channel region 902 may be formed in the second direction (e.g., the +y direction) crossing the first direction from the third source-drain region 413. A second source-drain region 412 and the third source-drain region 413 may be formed at opposite ends of the second channel region 902.

According to an embodiment, the gate electrode 880, when viewed from above the gate electrode 880, may be formed in a region other than the region overlapping the third source-drain region 413. At least a portion of the gate electrode 880, when viewed from above the gate electrode 880, may overlap the first channel region 901 and the second channel region 902.

The first source-drain region 411 and the third source-drain region 413 may form a first channel in the first channel region 901 in response to application of a voltage to the gate electrode 880. The second source-drain region 412 and the third source-drain region 413 may form a second channel in the second channel region 902 in response to application of a voltage to the gate electrode 880.

However, the channels formed through the first channel region 901 and the second channel region 902 may have various shapes (or, regions) in the first channel region 901 and the second channel region 902.

Referring to FIGS. 9 and 10A together, the first channel region 901 according to an embodiment may further include a first protrusion 911 protruding in a third direction (e.g., the +z direction). The second channel region 902 may further include a second protrusion 912 protruding in the third direction.

The third direction (e.g., the +z direction) may be understood as a direction perpendicular to the first direction (e.g., the +x direction) and the second direction (e.g., the +y direction). Furthermore, the third direction may be understood as a direction perpendicular to one surface on which the semiconductor device 200C is disposed.

Referring to FIG. 10B, at least a portion of the gate electrode 880 according to an embodiment may surround a first surface of the first protrusion 911 that faces in the third direction and a second surface and a third surface of the first protrusion 911 that extend from the first surface and face toward the device isolation pattern 290.

A gate insulating layer 460 may be formed by removing a partial region of the device isolation pattern 290 adjacent to the first protrusion 911 and performing an oxidation process on the removed region. The gate electrode 880 may be formed on the gate insulating layer 460 formed through the above-described oxidation process.

At least a portion of the gate electrode 880 may surround a fourth surface of the second protrusion 912 that faces toward the gate electrode 880 and a fifth surface and a sixth surface of the second protrusion 912 that extend from the fourth surface and face toward the device isolation pattern 290.

As described above, the semiconductor device 200C according to an embodiment may be formed in a form in which at least a portion of a channel region protrudes from one surface of a substrate 20 in a vertical direction (e.g., the third direction or the +z direction). The semiconductor device 200C may include the gate electrode 880 surrounding the protruding portion (e.g., the first protrusion 911 or the second protrusion 912) of the channel region.

Through the above-described configuration, the semiconductor device 200C according to the embodiment of the present may increase the area of the channel region (e.g., the first channel region 901 or the second channel region 902). In addition, the image sensor 100 according to the present disclosure may minimize noise of a signal output through the semiconductor device 200C and may improve the quality of the signal.

Referring to FIGS. 9, 11A, and 11B together, the semiconductor device 200C according to an embodiment may include the first channel region 901 formed in the first direction (e.g., the +x direction) under the gate electrode 880. In addition, the semiconductor device 200C may include the second channel region 902 formed in the second direction (e.g., the +y direction) crossing the first direction from the third source-drain region 413.

According to an embodiment, the third source-drain region 413 may have a third width W3 smaller than a first width W1 of the first source-drain region 411 and a second width W2 of the second source-drain region 412.

At least a portion of the third source-drain region 413 may be spaced apart from the periphery of a first region 310A. At least a portion of the third source-drain region 413 may be spaced apart from the device isolation pattern 290.

Referring to FIG. 11A, in an implementation, the first source-drain region 411 may have the first width W1. The third source-drain region 413 may have the third width W3 smaller than the first width W1 of the first source-drain region 411.

Accordingly, the third source-drain region 413 and the first source-drain region 411 may form the first channel region 901 at least partially spaced apart from the device isolation pattern 290. The first channel region 901 may have a first channel length L1 and may be formed in the first direction (e.g., the x direction).

According to an embodiment, a source-drain current may be generated along a path spaced apart from the device isolation pattern 290 in the first channel region 901 in response to application of a voltage to the gate electrode 880.

Referring to FIG. 11, the second source-drain region 412 may have the second width W2. The third source-drain region 413 may have the third width W3 smaller than the second width W2 of the second source-drain region 412.

Accordingly, the third source-drain region 413 and the second source-drain region 412 may form the second channel region 902 at least partially spaced apart from the device isolation pattern 290. The second channel region 902 may have a second channel length L2 and may be formed in the second direction (e.g., the y direction).

According to an embodiment, a source-drain current may be generated along a path spaced apart from the device isolation pattern 290 in the second channel region 902 in response to application of a voltage to the gate electrode 880.

Through the above-described configuration, the semiconductor device 200C may have a channel region (e.g., the first channel region 901 or the second channel region 902) at least partially spaced apart from the device isolation pattern 290.

Accordingly, the image sensor 100 according to the embodiment of the present disclosure may prevent (or, minimize) charge trapping that occurs in a region adjacent to the device isolation pattern 290 among the channels (or, the channel regions) of the transistor.

In addition, the image sensor 100 may reduce noise generated due to the charge trapping in the drive transistor 200.

As described above, the image sensor 100 according to the embodiment of the present disclosure may minimize noise due to a decrease in the channel area of the transistor formed in the region having a bent shape.

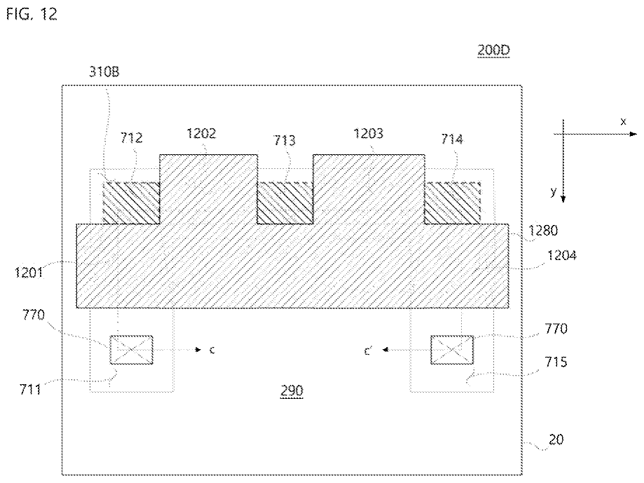

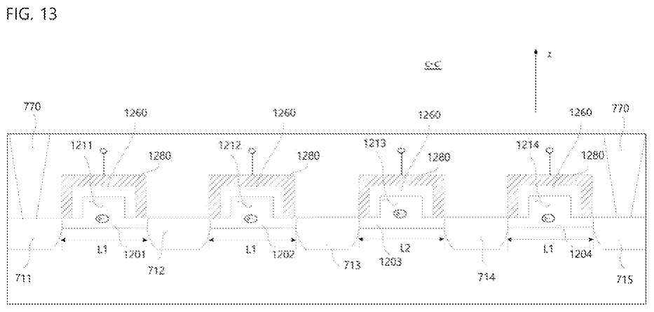

FIG. 12 shows a layout of a semiconductor device 200D according to another embodiment of the present disclosure. FIG. 13 shows a sectional view of the semiconductor device taken along line c-c′ in FIG. 12.

Referring to FIG. 12, the semiconductor device 200D according to an embodiment may include a gate electrode 1280, and a first channel region 1201, a second channel region 1202, a third channel region 1203, and a fourth channel region 1204 that are formed under the gate electrode 1280.

The semiconductor device 200D may be understood as an example of the drive transistor 200 of FIG. 2. Therefore, components that are the same as, or substantially the same as, the above-described components will be assigned with the same reference numerals, and repetitive descriptions will be omitted.

The first channel region 1201 may be formed in the second direction (e.g., the y direction) under the gate electrode 1280. A first source-drain region 711 and a second source-drain region 712 may be formed at opposite ends of the first channel region 1201.

The second channel region 1202 may be formed in the first direction (e.g., the x direction) crossing the second direction from the second source-drain region 1202. The second source-drain region 712 and a third source-drain region 713 may be formed at opposite ends of the second channel region 1202.

The third channel region 1203 may be formed in the first direction from the third source-drain region 713. The third source-drain region 713 and a fourth source-drain region 714 may be formed at opposite ends of the third channel region 1203.

The fourth channel region 1204 may be formed in the second direction from the fourth source-drain region 714. The fourth source-drain region 714 and a fifth source-drain region 715 may be formed at opposite ends of the fourth channel region 1204.

According to an embodiment, the gate electrode 1280, when viewed from above the gate electrode 1280, may be formed in a region other than the regions overlapping the first source-drain region 711, the second source-drain region 712, the third source-drain region 713, the fourth source-drain region 714, and the fifth source-drain region 715. At least a portion of the gate electrode 1280, when viewed from above the gate electrode 1280, may overlap the first channel region 1201, the second channel region 1202, the third channel region 1203, and the fourth channel region 1204.

The first source-drain region 711 and the second source-drain region 712 may form a first channel in the first channel region 1201 in response to application of a voltage to the gate electrode 1280.

The second source-drain region 712 and the third source-drain region 713 may form a second channel in the second channel region 1202 in response to application of a voltage to the gate electrode 1280.

The third source-drain region 713 and the fourth source-drain region 714 may form a third channel in the third channel region 1203 in response to application of a voltage to the gate electrode 1280.

The fourth source-drain region 714 and the fifth source-drain region 715 may form a fourth channel in the fourth channel region 1204 in response to application of a voltage to the gate electrode 1280.

Each of the above-described source-drain regions (the first to fifth source-drain regions 711 to 715) may form a transistor together with an adjacent source-drain region and the gate electrode 1280. In an implementation, the second source-drain region 712 may form a transistor together with the third source-drain region 713 and the gate electrode 1280. The third source-drain region 713 may form a transistor together with the fourth source-drain region 714 and the gate electrode 1280.

In an implementation, the second source-drain region 712 and the fourth source-drain region 714 may be referred to as source regions of the transistors. Furthermore, the first source-drain region 711, the third source-drain region 713, and the fifth source-drain region 715 may be referred to as drain regions of the transistors.

However, the distinction of the first source-drain region 711, the second source-drain region 712, the third source-drain region 713, the fourth source-drain region 714, and the fifth source-drain region 715 (e.g., a source region or a drain region) may be changed as needed.

Referring to FIGS. 12 and 13 together, the first channel region 1201 according to an embodiment may further include a first protrusion 1211 protruding in the third direction (e.g., the +z direction). The second channel region 1202 may further include a second protrusion 1212 protruding in the third direction. The third channel region 1203 and the fourth channel region 1204 may include a third protrusion 1213 and a fourth protrusion 1214, respectively, which protrude in the third direction.

The third direction (e.g., the +z direction) may be understood as a direction perpendicular to the first direction (e.g., the x direction) and the second direction (e.g., the y direction). Furthermore, the third direction may be understood as a direction perpendicular to one surface of a substrate 20 on which the semiconductor device 200D is disposed.

At least a portion of the gate electrode 1280 according to an embodiment may surround at least a part of the first to fourth protrusions 1211 to 1214.

In an implementation, the gate electrode 1280 may surround a first surface of the first protrusion 1211 that faces in the third direction and a second surface and a third surface of the first protrusion 1211 that extend from the first surface and face in the first direction or the second direction.

At least portions of the gate electrode 1280 may surround surfaces of the second to fourth protrusions 1212 to 1214 that face toward the gate electrode 1280 and side surfaces of the second to fourth protrusions 1212 to 1214 that extend from the surfaces and face in the first direction or the second direction.

A gate insulating layer 1260 may be formed by removing partial regions of the device isolation pattern 290 adjacent to the first to fourth protrusions 1211 to 1214 and performing an oxidation process on the removed regions. The gate electrode 1280 may be formed on the gate insulating layer 1260 formed through the above-described oxidation process.

As described above, the semiconductor device 200D according to an embodiment may be formed in a form in which at least a portion of a channel region protrudes from one surface of the substrate 20 in a vertical direction (e.g., the third direction or the +z direction). The semiconductor device 200D may include the gate electrode 1280 surrounding the protruding portions (e.g., the first protrusion 1211, the second protrusion 1212, the third protrusion 1213, and the fourth protrusion 1214) of the channel regions.

Through the above-described configuration, the semiconductor device 200D according to the embodiment of the present may increase the areas of the channel regions (e.g., the first channel region 1201, the second channel region 1202, the third channel region 1203, and the fourth channel region 1204). In addition, the image sensor 100 according to the present disclosure may minimize noise of a signal output through the semiconductor device 200D and may improve the quality of the signal.

The semiconductor devices according to the embodiments of the present disclosure may minimize noise due to a decrease in a channel area of a transistor.

By way of summation and review, a pixel array constituting a CMOS image sensor may include a photoelectric conversion element for each pixel. The photoelectric conversion element may generate an electrical signal that varies depending on the amount of incident light, and the CMOS image sensor may synthesize an image by processing the generated electrical signal. Depending on demands for high-resolution images, the pixels constituting the CMOS image sensor may be required to be more compact.

However, a drive transistor included in the CMOS image sensor may have a characteristic that noise increases as the area of a channel decreases.

Embodiments of the present disclosure provide a semiconductor device for minimizing noise due to a decrease in a channel area of a transistor.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a gate electrode;
a first region under the gate electrode and extending from a first direction to a second direction crossing the first direction, the first region having a bent shape;
a first source-drain region extending from one end of the first region;
a second source-drain region extending from an opposite end of the first region; and
a third source-drain region at a point where a first virtual straight line extending from the first source-drain region in the first direction and a second virtual straight line extending from the second source-drain region in a direction opposite to the second direction cross each other in the first region,
wherein the third source-drain region forms a first channel region together with the first source-drain region and forms a second channel region together with the second source-drain region.

2. The semiconductor device as claimed in claim 1, wherein the first channel region and the second channel region are connected in parallel as the first source-drain region and the second source-drain region are electrically connected.

3. The semiconductor device as claimed in claim 1, wherein:
the first source-drain region has a first width corresponding to a width of the one end of the first region,
the second source-drain region has a second width corresponding to a width of the opposite end of the first region, and
the third source-drain region has a third width smaller than the first width and the second width.

4. The semiconductor device as claimed in claim 3, wherein the third source-drain region is in the first region and spaced apart from a periphery of the first region.

5. The semiconductor device as claimed in claim 3, further comprising a device isolation pattern adjacent to a periphery of the first region and electrically isolating the first region,
wherein at least a portion of the first channel region and at least a portion of the second channel region are spaced apart from the device isolation pattern in response to application of a voltage to the gate electrode.

6. The semiconductor device as claimed in claim 5, wherein the gate electrode, when viewed from above the gate electrode, is in a region overlapping the first channel region and the second channel region in the first region.

7. The semiconductor device as claimed in claim 6, wherein at least a portion of the first channel region of the first region includes a first protrusion protruding in a third direction toward the gate electrode, the third direction being perpendicular to the first direction and the second direction.

8. The semiconductor device as claimed in claim 7, wherein at least a portion of the gate electrode surrounds a first surface of the first protrusion facing in the third direction and a second surface and a third surface of the first protrusion extending from the first surface and facing toward the device isolation pattern.

9. A semiconductor device, comprising:
a gate electrode;
a first channel region extending in a first direction under the gate electrode;
a first source-drain region and a second source-drain region at opposite ends of the first channel region;
a second channel region extending in a second direction crossing the first direction from the second source-drain region;
a third source-drain region at an opposite end of the second channel region;
a third channel region extending in the second direction from the third source-drain region;
a fourth source-drain region at an opposite end of the third channel region;
a fourth channel region extending in a direction opposite to the first direction from the fourth source-drain region; and
a fifth source-drain region at an opposite end of the fourth channel region,
wherein the second source-drain region, the third source-drain region, and the fourth source-drain region have a third width smaller than a first width of the first source-drain region and a second width of the fifth source-drain region.

10. The semiconductor device as claimed in claim 9, wherein:
the first source-drain region and the fifth source-drain region are electrically connected,
the second source-drain region and the fourth source-drain region are electrically connected, and
the first channel region and the fourth channel region are connected in parallel.

11. The semiconductor device as claimed in claim 9, wherein the second channel region and the third channel region are connected in parallel.

12. The semiconductor device as claimed in claim 9, further comprising a device isolation pattern electrically isolating at least a portion of the semiconductor device,
wherein at least a portion of the first channel region, at least a portion of the second channel region, at least a portion of the third channel region, and at least a portion of the fourth channel region are spaced apart from the device isolation pattern.

13. The semiconductor device as claimed in claim 12, wherein the gate electrode, when viewed from above the gate electrode, is in a region overlapping the first channel region, the second channel region, the third channel region, and the fourth channel region.

14. The semiconductor device as claimed in claim 13, wherein at least a portion of the first channel region includes a first protrusion protruding in a third direction toward the gate electrode, the third direction being perpendicular to the first direction and the second direction.

15. The semiconductor device as claimed in claim 14, wherein the gate electrode surrounds a first surface of the first protrusion facing in the third direction and a second surface and a third surface of the first protrusion extending from the first surface and facing toward the device isolation pattern.

16. An image sensor, comprising:
a photo diode configured to generate electric charges in response to incident light;
a drive transistor configured to generate a source-drain current depending on the incident light, based on an output of the photo diode;
a transfer transistor configured to transfer the output of the photo diode to the drive transistor; and
a device isolation pattern configured to isolate the drive transistor from a ground,
wherein:
the drive transistor includes:
a gate electrode,
a first channel region extending in a first direction under the gate electrode,
a first source-drain region and a third source-drain region at opposite ends of the first channel region,
a second channel region extending in a second direction crossing the first direction from the third source-drain region, and
a second source-drain region at an opposite end of the second channel region, and
at least a portion of the first channel region and at least a portion of the second channel region are spaced apart from the device isolation pattern.

17. The image sensor as claimed in claim 16, wherein the first channel region and the second channel region are connected in parallel as the first source-drain region and the second source-drain region are electrically connected.

18. The image sensor as claimed in claim 16, wherein the third source-drain region has a third width smaller than a first width of the first source-drain region and a second width of the second source-drain region.

19. The image sensor as claimed in claim 16, wherein at least a portion of the first channel region includes a first protrusion protruding in a third direction toward the gate electrode, the third direction being perpendicular to the first direction and the second direction.

20. The image sensor as claimed in claim 19, wherein the gate electrode surrounds a first surface of the first protrusion facing in the third direction and a second surface and a third surface of the first protrusion extending from the first surface and facing toward the device isolation pattern.
